(19) United States
(12) Patent Application Publication
(10) Pub. No.: US 2022/0190842 A1
(43) Pub. Date: Jun. 16, 2022

(54) EMBEDDED DEEP COMPRESSION FOR TIME-SERIES DATA

(71) Applicants: Siemens Corporation, lsetin, NJ (US); Stanford University, Palo Alto, CA (US)

(72) Inventors: Chengtao Wen, Redwood City, CA (US); Lingyun Wang, Princeton, NJ (US); Juan L. Aparicio Ojea, Moraga, CA (US); Shubham Chandak, Palo Alto, CA (US); Kedar Shriram Tatwawadi, Santa Clara, CA (US); Tsachy Weissman, Stanford, CA (US)

(21) Appl. No.: 17/439,836

(22) PCT Filed: Mar. 22, 2019
(86) PCT No.: PCT/US2019/023501

§ 371 Date: Sep. 16, 2021

(51) Int. Cl. H03M 7/30; G06N 3/08

(52) U.S. Cl. CPC H03M 7/3059; G06N 3/08

(57) ABSTRACT

A lossy compression algorithm is described for performing data compression of high-frequency floating point time-series data, for example. The compression algorithm utilizes a prediction engine that employs at least one of a linear prediction model or a non-linear prediction model to calculate one-step-ahead prediction of a current data value at current sampling time t using N previous quantized data values, where N is the model order. A prediction error is determined between the predicted value and an actual value, and the prediction error is quantized. A quantized current data value is determined from the predicted value and the quantized prediction error. The quantized prediction error is sent from an edge device to a data decompressor on a cloud device. The decompressor reconstructs the quantized current data value using the received quantized prediction error and by generating the same predicted value as the compressor.

### BACKGROUND

The present invention relates generally to data compression, and more particularly, to embedded deep compression for time-series data.

The capability to perform real-time analysis of collected data and make real-time decisions based thereon is of critical importance to the modern manufacturing industry. The large amount of manufacturing data that typically needs to be analyzed coupled with network bandwidth constraints necessitates the use of data compression algorithms capable of reducing the amount of data that needs to be transferred between a device that collects the data and a device that processes the data, while ensuring that a desired accuracy is maintained.

Smart machines and sensors, for example, typically generate measurements at very high frequencies, leading to a need to transmit a very large amount of data through constrained computation and bandwidth resources between edge devices and cloud platforms. Moreover, some manufacturing data must be instantly accessible at all times such as guidance and control data for automated guided vehicles. Data compression algorithms for compressing data such as time-series manufacturing data, however, suffer from a number of technical drawbacks, technical solutions to which are described herein.

### SUMMARY

In one or more example embodiments, a computer-implemented method for compressing time-series data is disclosed. The method includes receiving input that includes a collection of prior quantized data values and receiving learned parameters of one or more prediction models. The method further includes determining, using the one or more prediction models, a predicted current data value based at least in part on the collection of prior quantized data values and the learned parameters and determining a prediction error based at least in part on the predicted current data value and an actual current data value. The method additionally includes quantizing the prediction error to obtain a quantized prediction error and determining a quantized current data value based at least in part on the quantized prediction error and the predicted current data value. The method further includes re-learning the parameters based at least in part on the collection of prior quantized data values and the quantized current data value.

In one or more other example embodiments, a system for compressing time-series data is disclosed. The system includes at least one memory storing computer-executable instructions and at least one processor configured to access the at least one memory and execute the computer-executable instructions to perform a set of operations. The operations include receiving input that includes a collection of prior quantized data values and receiving learned parameters of one or more prediction models. The operations further include determining, using the one or more prediction models, a predicted current data value based at least in part on the collection of prior quantized data values and the learned parameters and determining a prediction error based at least in part on the predicted current data value and an actual current data value. The operations additionally include quantizing the prediction error to obtain a quantized prediction error and determining a quantized current data value based at least in part on the quantized prediction error and the predicted current data value. The operations further include re-learning the parameters based at least in part on the collection of prior quantized data values and the quantized current data value.

In one or more other example embodiments, a computer program product for compressing time-series data is disclosed. The computer program product includes a non-transitory storage medium readable by a processing circuit, the storage medium storing instructions executable by the processing circuit to cause a method to be performed. The method includes receiving input that includes a collection of prior quantized data values and receiving learned parameters of one or more prediction models. The method further includes determining, using the one or more prediction models, a predicted current data value based at least in part on the collection of prior quantized data values and the learned parameters and determining a prediction error based at least in part on the predicted current data value and an actual current data value. The method additionally includes quantizing the prediction error to obtain a quantized prediction error and determining a quantized current data value based at least in part on the quantized prediction error and the predicted current data value. The method further includes re-learning the parameters based at least in part on the collection of prior quantized data values and the quantized current data value.

In one or more example embodiments, a computer-implemented method for decompressing compressed time-series data is disclosed. The method includes receiving input that includes a collection of prior quantized data values, receiving learned parameters of one or more prediction models, and receiving, from a data compressor, a compressed quantized prediction error. The method further includes decompressing the compressed quantized prediction error to obtain a quantized prediction error and determining, using the one or more prediction models, a predicted current data value based at least in part on the collection of prior quantized data values and the learned parameters. The method additionally includes reconstructing a quantized current data value based at least in part on the quantized prediction error and the predicted current data value and re-learning the parameters based at least in part on the collection of prior quantized data values and the quantized current data value.

Example embodiments of the invention also relate to systems and computer program products configured to implement the above-described method for decompressing compressed time-series data.

### BRIEF DESCRIPTION OF THE DRAWINGS

The detailed description is set forth with reference to the accompanying drawings. The drawings are provided for purposes of illustration only and merely depict example embodiments of the invention. The drawings are provided to facilitate understanding of the invention and shall not be deemed to limit the breadth, scope, or applicability of the invention. In the drawings, the left-most digit(s) of a reference numeral identifies the drawing in which the reference numeral first appears. The use of the same reference numerals indicates similar, but not necessarily the same or identical components. However, different reference numerals may be used to identify similar components as well. Various embodiments may utilize elements or components other than those illustrated in the drawings, and some elements and/or components may not be present in various embodiments. The use of singular terminology to describe a component or element may, depending on the context, encompass a plural number of such components or elements and vice versa.

FIG. 1 is a schematic hybrid data flow/block diagram illustrating operation of a self-learning data compressor in accordance with one or more example embodiments of the invention.

FIG. 2 is a schematic hybrid data flow/block diagram illustrating operation of a self-learning data decompressor in accordance with one or more example embodiments of the invention.

FIG. 3 is a process flow diagram of an illustrative method for compressing time-series data using a self-learning data compressor in accordance with one or more example embodiments of the invention.

FIG. 4 is a process flow diagram of an illustrative method for decompressing compressed time-series data using a self-learning data decompressor in accordance with one or more example embodiments of the invention.

FIG. 5 is a schematic diagram of an illustrative networked architecture configured to implement one or more example embodiments of the invention.

### DETAILED DESCRIPTION

Example embodiments relate to, among other things, devices, systems, methods, computer-readable media, techniques, and methodologies for performing embedded deep compression of time-series data. More specifically, example embodiments relate to a lossy compression algorithm for performing data compression of high-frequency floating point time-series data, for example. A lossy compression algorithm in accordance with example embodiments utilizes a prediction engine that employs at least one of a linear prediction model or a non-linear prediction model to calculate one-step-ahead prediction of a current data value at current sampling time t using N previous quantized data values, where N is the model order.

In example embodiments, a prediction error εₜ is calculated as the difference between the predicted current data value \tilde{y}ₜ at sampling time t and an actual current data value yₜ at sampling time t. In example embodiments, the prediction error εₜ is quantized by a quantizer engine to obtain a quantized prediction error êₜ, which may then be compressed and stored. Further, in example embodiments, a quantized current data value ŷₜ for sampling time t is calculated as the sum of the quantized prediction error \hat{ε}ₜ and the predicted current data value \tilde{y}ₜ. Parameters of the predictive model(s) employed by the prediction engine can then be re-learned using the quantized current data value ŷₜ in conjunction with the N previous quantized data values. The above-described compression algorithm can be iteratively performed to continually refine the parameters of the predictive model(s) and improve the accuracy with respect to any given compression ratio.

In example embodiments, a data compressor configured to execute a lossy data compression algorithm in accordance with example embodiments may reside on a network edge device. For instance, the data compressor may reside and execute on an embedded device including, without limitation, an industrial controller (e.g., a programmable logic controller (PLC)); a smart sensor (e.g., a temperature sensor, a vibration sensor, etc.); or any other device capable of collecting time-series data measurements. In certain example embodiments, training of the predictive model(s) utilized by the prediction engine of the data compressor may be the most computationally intensive aspect of executing the compression algorithm. As such, in example embodiments, the predictive model(s) may be trained offline on a cloud device that includes more computational resources than the network edge device that collects the data and performs the compression. However, a self-learning compression algorithm in accordance with example embodiments of the invention can also be efficiently trained on embedded hardware as well.

In example embodiments, the quantized prediction error \hat{ε}ₜ is sent from a data compressor executing on an edge device to a data decompressor executing on a cloud device. The data decompressor executing on the cloud device may include the same prediction engine that employs the same trained predictive model(s) as the data compressor. As such, in example embodiments, the predictive engine of the data decompressor calculates the same predicted current data value \tilde{y}ₜ as the predictive engine of the data compressor. The data decompressor may then be configured to reconstruct the quantized current data value ŷₜ for sampling time t based at least in part on the quantized prediction error \hat{ε}ₜ and the predicted current data value \tilde{y}ₜ. More specifically, in example embodiments, the data decompressor reconstructs the same quantized current data value ŷₜ as that determined by the data compressor by summing the quantized prediction error \hat{ε}ₜ and the predicted current data value \tilde{y}ₜ.

In example embodiments, the parameters of the model(s) employed by the prediction engine are learned using, for example, a supervised learning algorithm. In example embodiments, the learned parameters include user-friendly tuning parameters designed to control the accuracy/speed tradeoff for data compression. The accuracy/speed tradeoff refers to the inverse relationship between compression rate (also referred to herein as compression ratio)—which is a ratio of the size of the original data to the size of the compressed data—and accuracy, which is the extent of information loss introduced by the compression. Generally speaking, the higher the compression ratio (i.e., the more the data is compressed), the lower the accuracy of the compression. In example embodiments, the compression ratio depends on the accuracy of the prediction made by the prediction engine. For instance, if the prediction is good, the prediction error will be small, and thus, the output of the quantizer engine will be zero or close to zero. This, in turn, reduces the bandwidth requirements for transferring the quantized prediction errors from edge devices to a data decompressor residing on a cloud device.

Various parameters of predictive model(s) used in connection with a lossy compression algorithm according to example embodiments of the invention may be tuned to control the accuracy/speed tradeoff with respect to specific application scenarios and types of data being compressed. For instance, certain application scenarios may involve data that exhibits a greater degree of periodicity and less variation over time. In such example application scenarios, a certain amount of accuracy may be sacrificed to achieve a higher compression ratio, and thus, for such example application scenarios, the predictive model parameters may be tuned to favor a higher compression ratio over accuracy. In other example application scenarios, such as those in which the time-series data exhibits a high degree of variability over time (e.g., vibration data), it may be desirable to maintain a higher degree of accuracy at the expense of a lower compression ratio. In such example application scenarios, the predictive model parameters may be tuned to favor accuracy over compression ratio. Further, in yet other example embodiments, the parameters may be turned to achieve different accuracy/speed tradeoffs at different sampling times for the same time-series data.

In addition, in example embodiments, the predictive engine may employ a non-linear predictive model (e.g., a non-linear deep neural network) that is capable of efficiently handling compression of time-series data that exhibits a high degree of time-variant non-linearity (e.g., vibration data). The non-linear predictive model may be able to capture both short-term and long-term data dependencies in the time-series data. For instance, in contrast to a linear model alone, the non-linear predictive model may recognize periodic patterns in the time-series data over time and perform compression based thereon. Thus, in example embodiments, the combined use of linear and non-linear predictive models coupled with the ability to self-learn tuning parameters to control the accuracy/speed tradeoff enables fast and robust compression across a wider range of application scenarios and types of data—such as data that exhibits a high degree of variability and/or unpredictability—than conventional data compression algorithms.

For instance, speed data may exhibit smooth piecewise linear behaviors; power meter data may exhibit piecewise linear behavior with small oscillations; and vibration data may exhibit strongly non-linear behaviors with high frequency oscillations over zero mean. Thus, a lossy compression algorithm in accordance with example embodiments allows for the efficient monitoring, communication, storage, processing, analysis, and visualization of each of these types of data representing a much wider range of industrial data than conventional compression algorithms are capable of efficiently handling. It should be appreciated that the time-series data to which example embodiments of the invention are applicable can include, without limitation, pressure data; temperature data; fluid flow rate data; velocity data; acceleration data; and any other data relating to physical, chemical, or biological parameters.

Generally speaking, there are two fundamental classes of conventional data compression algorithms. The first class identifies and removes repeating elements in the original data. For example, this class of compression algorithms may compress text data by identifying repeating terms/phrases in the text and storing, for each repetition of a term/phrase, a pointer to a prior occurrence of the term/phrase. These algorithms are generally lossless, where the original data is represented without losing any information, and the process is reversible. However, with this class of compression algorithms, the compression and decompression are often computationally intensive, thereby limiting a wider application of these compression algorithms to time-sensitive compression tasks like fast sampling of manufacturing processes such as vibration control.

The second class of compression algorithms seeks to identify redundant data and discard the redundant data to achieve a predefined compression accuracy. Typical examples include collector compression algorithms and archive compression algorithms. Collector compression algorithms examine the values of measured data and discard those values that stay within a defined value range (e.g., ±1 mm for distance measurements and ±10 Pascal for pressure measurements). Stated more generally, collector compression algorithms store data based on the amount of change in the data. Thus, collector compression algorithms only record a new value when that new value deviates more than a threshold amount from a last recorded value. Archive compression algorithms, on the other hand, store data based on its rate of change. More specifically, archive compression algorithms, also known as swinging door compression algorithms, examine the slope of measured data and discard those values that fall within a predefined slope range. Generally speaking, archive compression algorithms store data that changes direction beyond a configured range. In general, both collection compression algorithms and archive compression algorithms are lossy compressors, and in some cases, archive compression can be run after running collection compression.

The above-described classes of conventional compression algorithms suffer from a number of technical drawbacks, which are addressed by the self-learning compression algorithms according to example embodiments of the invention. Specifically, the first class of compression algorithms described above are computationally intensive, and thus, unsuitable for time-sensitive compression tasks such as compression of fast-sampled time-series data. While the second class of compression algorithms described above may be more suitable for time-sensitive compression tasks, they (as well as the first class of compression algorithms) are incapable of providing fast and efficient compression for time-series data that exhibits non-linearities and/or fast-changing and rapidly fluctuating data measurements. For instance, if time-series data exhibits non-linear structures and/or rapidly fluctuating data values, these conventional algorithms would yield a very low compression ratio in order to maintain a desired accuracy. In contrast, a lossy compression algorithm in accordance with example embodiments is capable of achieving a much higher compression ratio at the desired accuracy for time-series data that exhibits non-linear structures and/or rapidly fluctuating data values by utilizing predictive model(s) including, for example, non-linear deep neural networks to predict current data values based on a prior data values. If the prediction is good, the prediction errors are small, and thus, the quantized prediction errors will be zero or close to zero most of the time, thereby reducing the bandwidth requirements for transferring the quantized errors from edge devices to cloud devices.

In particular, example embodiments of the invention relate to an improved lossy data compression algorithm that includes a number of technical features that yield a technical effect representing an improvement over conventional data compression algorithms, and thus, an improvement to computer technology. More specifically, example embodiments of the invention relate to a self-learning compression algorithm that leverages deep-learning technologies and compression methods to achieve more efficient data compression across a broader range of application scenarios and types of time-series data than conventional compression algorithms. In particular, a self-learning compression algorithm in accordance with example embodiments includes the technical features of: 1) utilizing a non-linear predictive model such as a non-linear deep neural network to enable capturing long-term data dependencies in time-series data that exhibits non-linearities, 2) quantization of the prediction errors, which is particularly suited to highly variable data with a fast sampling frequency, and 3) online or offline self-learning of time-variant parameters of the predictive model(s) using efficient supervised learning algorithms in order to achieve a desired accuracy/speed tradeoff.

The above-described technical features of example embodiments of the invention yield the technical effect of being able to perform real-time compression of time-series data on embedded hardware such as an industrial controller or smart sensor. In particular, a non-linear compressor having self-learning capability in accordance with example embodiments of the invention provides fast and reliable compression that is customized to time-series data, and thus, can be deployed in industrial settings such as in connection with flexible manufacturing systems; industrial Internet of Things (IoT) platforms; supply chain management; industrial data visualization; and so forth. This represents an improvement to computer technology—specifically computer-based data compression technology—because conventional compression algorithms require a prohibitively large amount of computational resources that make executing such algorithms on embedded hardware infeasible. In addition, example embodiments of the invention provide an advantage over conventional compression algorithms of training non-linear deep neural network models on embedded devices to enable fast sampling of time-series data in real manufacturing processes.

Moreover, as previously described, technical features of example embodiments of the invention include feeding deep neural network models with quantization-based lossy compression into a deep-learning framework to yield the technical effect of real-time data compression with a self-learning capability. This technical effect provides an improvement over conventional compression algorithms by enabling the reduction of data dependencies in generic time-series data by utilizing long short-term features stored in the deep neural networks.

In addition, even if a lossy compression algorithm in accordance with example embodiments of the invention utilizes only a linear predictive model (and not a non-linear model), a greater compression ratio is achieved at any given accuracy over conventional compression algorithms. This is the case because if the data fluctuates rapidly and exhibits non-linearities, conventional compression algorithms would need to record essentially every value, whereas a compression algorithm in accordance with example embodiments would still achieve some level of compression due to the quantization of the prediction errors.

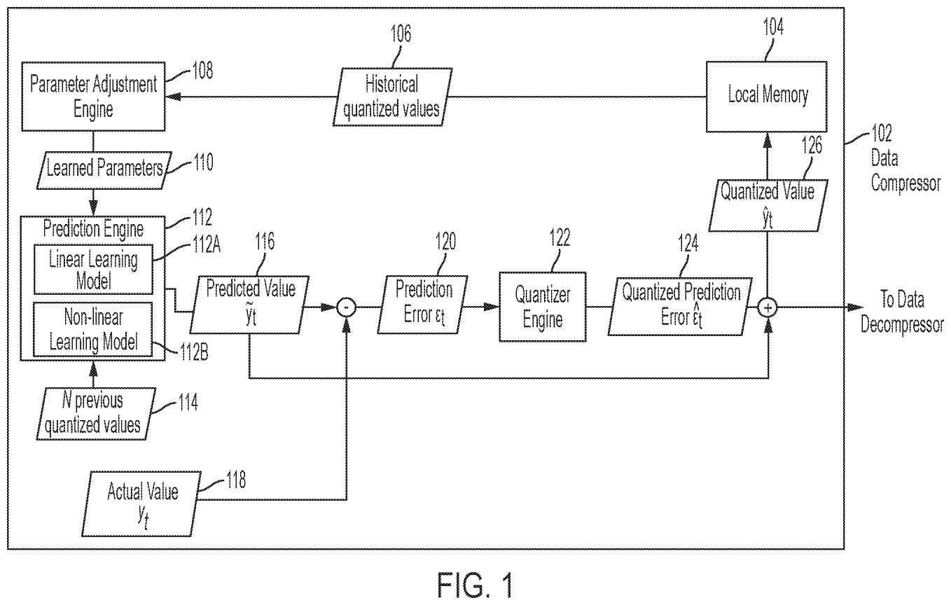

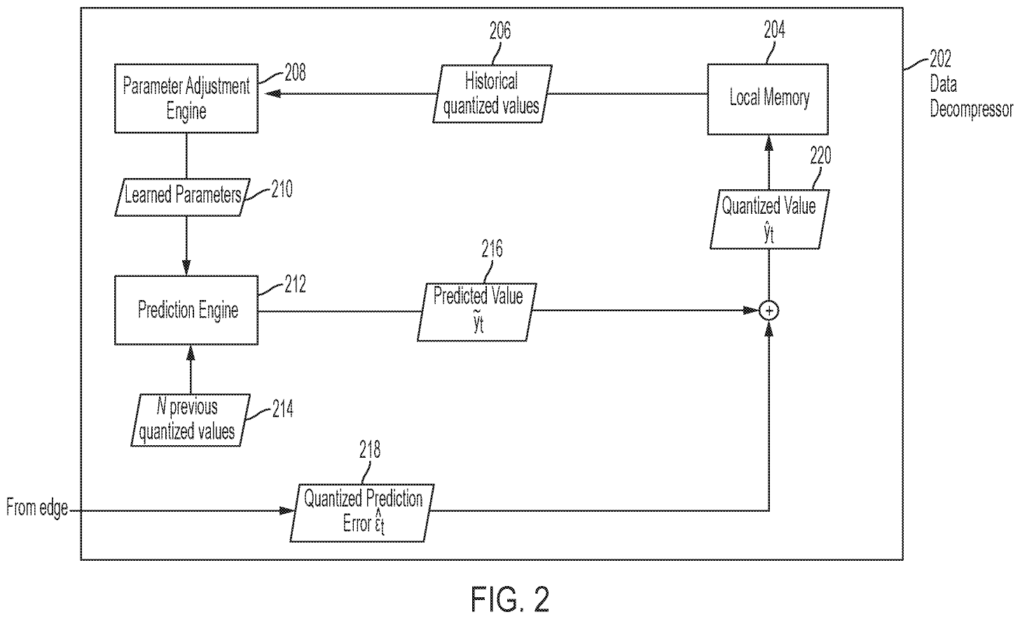

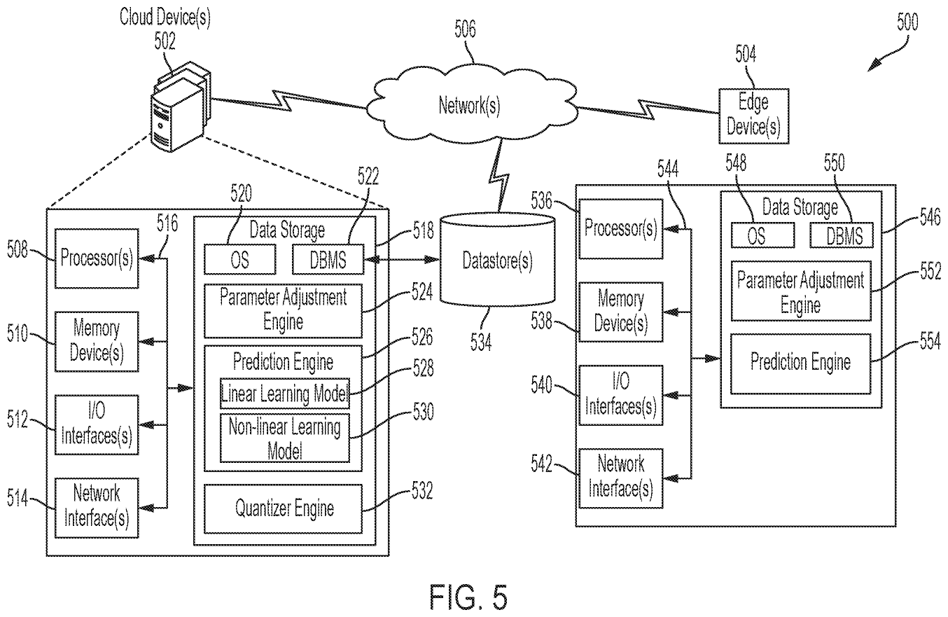

Illustrative methods in accordance with example embodiments of the invention and corresponding data structures (e.g., engines/program modules) for performing the methods will now be described. It should be noted that each operation of the method 300 and/or the method 400 may be performed by one or more of the engines/program modules depicted in FIG. 1, FIG. 2, and/or FIG. 5, whose operation will be described in more detail hereinafter. These engines/program modules may be implemented in any combination of hardware, software, and/or firmware. In certain example embodiments, one or more of these engines/program modules may be implemented, at least in part, as software and/or firmware modules that include computer-executable instructions that when executed by a processing circuit cause one or more operations to be performed. A system or device described herein as being configured to implement example embodiments may include one or more processing circuits, each of which may include one or more processing units or nodes. Computer-executable instructions may include computer-executable program code that when executed by a processing unit may cause input data contained in or referenced by the computer-executable program code to be accessed and processed to yield output data.

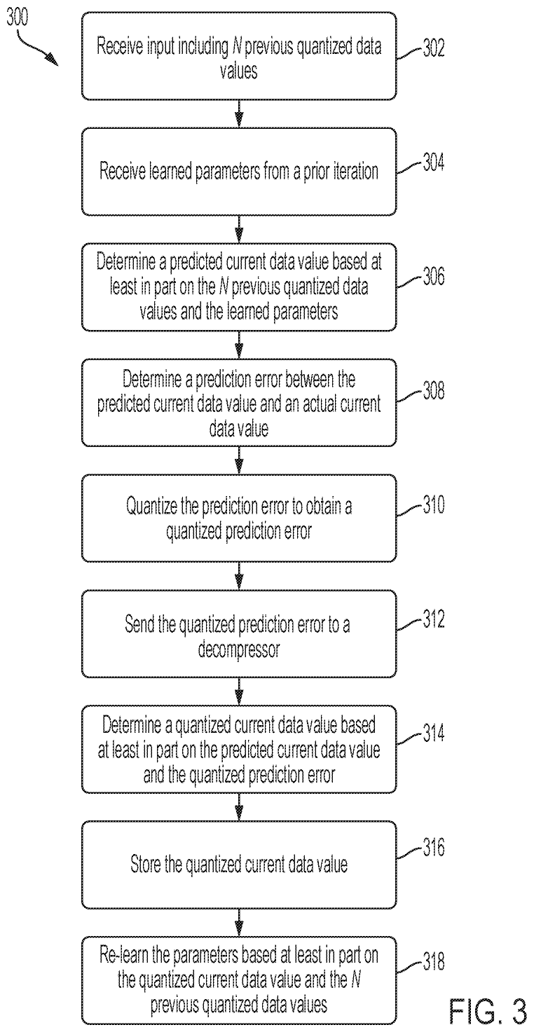

FIG. 1 is a schematic hybrid data flow/block diagram illustrating operation of a self-learning data compressor 102 in accordance with one or more example embodiments of the invention. FIG. 3 is a process flow diagram of an illustrative method 300 for compressing time-series data using, for example, the self-learning data compressor 102 in accordance with one or more example embodiments of the invention. FIGS. 1 and 3 will be described on conjunction with one another hereinafter.

An exemplary architecture of a data compressor 102 in accordance with example embodiments is depicted in FIG. 1. The data compressor 102 may include a local memory 104 for storing various types of data including, without limitation, quantized prediction errors, quantized data values, and the like. The data compressor 102 may further include a parameter adjustment engine 108 configured to re-learn and adjust predictive model parameters at each iteration of the algorithm. The data compressor 102 may additionally include a prediction engine 112 that may be configured to perform one-step ahead prediction. In example embodiments, the prediction engine 112 may include a linear learning model 112A and/or a non-linear learning model 112B. The terms learning model and predictive model may be used interchangeably herein. Still further, the data compressor 102 may include a quantizer engine 122 configured to quantize prediction errors. In example embodiments, the quantizer engine 122 may quantize a prediction error to a nearest integer value. In other example embodiments, the quantizer engine 122 may quantize a prediction error in accordance with a desired accuracy (e.g., two places after the decimal point).

Referring now to FIG. 3 in conjunction with FIG. 1, at block 302 of the method 300, the prediction engine 112 may receive input including N previous quantized data values 114. In example embodiments, the N previous quantized data values may be represented as follows: {ŷ_{t-N}, . . . , ŷₜ₋₁}, where t is current sampling time, and N is model order. In addition, at block 304 of the method 300, the prediction engine 112 may receive learned parameters 110 from a prior iteration of the compression algorithm.

In example embodiments, the learned parameters 110 may be utilized by the linear learning model 112A and/or the non-linear learning model 112B to perform the predictions. More specifically, the parameters 110 may be learned as part of training the linear learning model 112A and/or the non-linear learning model 112B using, for example, a supervised learning algorithm. In certain example embodiments, the parameters 110 may be re-learned at each iteration of the compression algorithm based on historical quantized data values 106. More specifically, in example embodiments, the parameter adjustment engine 108 may learn/re-learn the parameters 110 at each iteration of the compression algorithm based on the historical quantized data values 106 determined prior to the current sampling time t. For instance, the learned parameters 110 utilized by the prediction engine 112 at sampling time t can be represented as θₜ₋₁, indicating that the parameters are learned/re-learned based on historical quantized data values 106 associated with sampling times prior to time t, where the historical quantized data values 106 can be represented as {ŷ_{t-N}, . . . , ŷₜ₋₁} for t=1, . . . , T.

In other example embodiments, the parameters 110 may be learned and the learning model(s) of the prediction engine 112 trained offline based on ground-truth time-series data. In such example embodiments, as training the predictive engine 112 is the most computationally intensive task of the data compressor 102, the training may be performed offline on a cloud device with more computational resources, and the trained model(s) can then be downloaded for use on an edge device. In yet other example embodiments, the training may be performed at periodic intervals on an edge device in order to relieve some of the computational load on the edge device.

Referring again to FIG. 3, at block 306 of the method 300, the prediction engine 112 may determine a predicted current data value \tilde{y}ₜ 116 based at least in part on the N previous quantized data values {ŷ_{t-N}, . . . , ŷₜ₋₁} 114 and the learned parameters 110 θₜ₋₁. As previously described, the prediction engine 112 may include a linear learning model 112A and/or a non-linear learning model 112B. In example embodiments, the linear self-learning model 112A may be a Normalized Least Mean Square (NLMS) model and the non-linear self-learning model 112B may be a Long Short Term Memory (LSTM) model. Further, in example embodiments, real-time supervised learning algorithms may be implemented to learn the time-variant model parameters 110 utilized by the models.

In example embodiments, the parameters of the NLMS model 112A may be learned by minimizing the mean square error of the prediction. The NLMS model 112A may be an extension of an LMS predictor, which uses a different learning rate schedule to ensure better stability via normalizing with the power of the input signals. In example embodiments, an n-th order NLMS predictor may be used, wherein n is selected such that higher order models yield less than a threshold improvement in prediction/compression. For instance, in example embodiments, a 4^{th} order adaptive NLMS predictor that is implemented as follows may be used:

\tilde{y}ₜ=w₁·ŷₜ₋₁+w₂·ŷₜ₋₂+w₃·ŷₜ₋₃+w₄·ŷₜ₋₄.

In example embodiments, the LSTM-based deep neural network 112B may achieve higher compression ratios by capturing long term dependencies in the time-series data. In example embodiments, a log-loss function may be used as the loss function for the LSTM-based deep neural network 112B and L2 regularization may be added. In particular, in example embodiments, the supervised learning algorithm used to train the NLMS model 112A and/or the LSTM-based deep neural network 112B may seek to minimize, at each sampling time t, the L2 norm of the quantized prediction errors {\hat{ε}₁, . . . , \hat{ε}ₜ₋₁}.

Referring again to FIG. 3, at block 308 of the method 300, a prediction error εₜ 120 between the predicted current data value \tilde{y}ₜ 116 and an actual current data value yₜ 118 may be determined. More specifically, at block 308 of the method 300, the prediction error εₜ 120 may be calculated as the difference between the actual current data value yₜ 118 and the predicted current data value \tilde{y}ₜ 116.

Then, at block 310 of the method 300, the prediction error εₜ 120 is provided as input to a quantizer engine 122 that quantizes the prediction error εₜ 120 to obtain a quantized prediction error \hat{ε}ₜ 124. At block 312 of the method 300, the quantized prediction error \hat{ε}ₜ 124 may be sent to a data decompressor residing, for example, on a cloud device (e.g., data decompressor 202, FIG. 2). In example embodiments, a vector of quantized errors {\hat{ε}₁, . . . , \hat{ε}ₜ} including the quantized prediction error \hat{ε}ₜ 124 may be compressed and sent to the data decompressor in batch. For instance, in example embodiments, the quantizer engine 122 may be a uniform scalar quantizer, whose simplicity of design and implementation makes it particularly suited for small embedded devices. Outputs of the quantizer engine 122 may be compressed by a universal compressor (e.g., 7-zip). In example embodiments, the relative maximum error may be the design parameter used to select the spacing between the quantization bins. The quantizer engine 122 when implemented as a scalar quantizer may quantize each step independently, which can be suboptimal in certain instances. However, due to compression of the prediction errors using a universal compressor, any such sub-optimality would be very small. For example, if the quantization output is 0 for many consecutive steps, that output is capable of being compressed.

Referring again to FIG. 3, at block 314 of the method 300, a quantized current data value ŷₜ 126 may be determined based at least in part on the quantized prediction error \hat{ε}ₜ 124 and the predicted value \tilde{y}ₜ 116. More specifically, at block 314 of the method 300, the quantized current data value ŷₜ 126 may be calculated as the sum of the quantized prediction error \hat{ε}ₜ 124 and the predicted value \tilde{y}ₜ 116. At block 316 of the method 300, the quantized current data value ŷₜ 126 may be stored, for example, in the local memory 104. Finally, at block 318 of the method 300, the parameters 110 may be re-learned based at least in part on the quantized current data value ŷₜ 126 and the N previous quantized data values {ŷ_{t-N}, . . . , ŷₜ₋₁} 114. More specifically, θₜ may be determined based at least in part on (ŷ_{t-N}, . . . , ŷₜ) and θₜ, and θₜ may be used as the learned parameters 110 during a subsequent iteration of the compression algorithm at sampling time t+1.

Illustrative pseudocode corresponding to the operation of the data compressor 102 is shown below.

Input: {ŷ_{t-N}, . . . , ŷₜ₋₁}

Output: {\hat{ε}ₜ}

For t=1, . . . , T
1. yₜ=Predictor(ŷ_{t-N}, . . . , ŷₜ₋₁);
2. \hat{ε}=Quantizer(yₙ−\tilde{y}ₜ);
3. Send \hat{ε}ₜ to the decompressor
4. ŷₜ=\tilde{y}ₜ+\hat{ε}ₜ;
5. θₜ=Learner(ŷₜ₋ₙ, . . . , ŷₜ, θₜ₋₁).

End

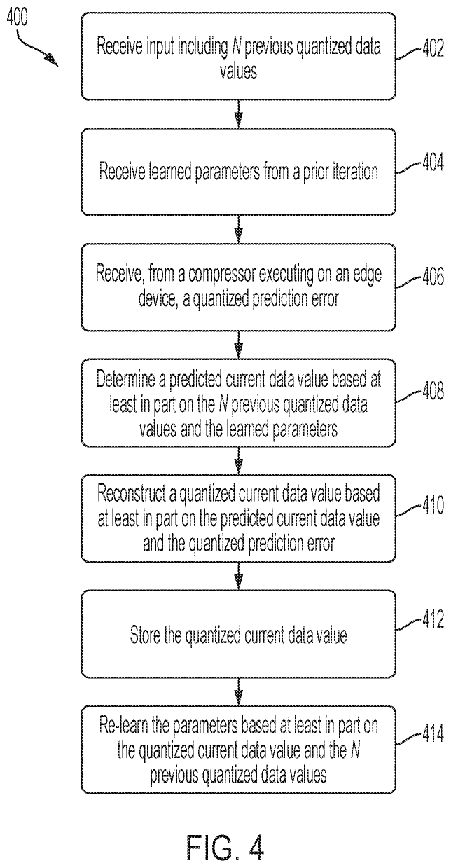

FIG. 2 is a schematic hybrid data flow/block diagram illustrating operation of a self-learning data decompressor 202 in accordance with one or more example embodiments of the invention. FIG. 4 is a process flow diagram of an illustrative method 400 for decompressing compressed time-series data using, for example, the self-learning data decompressor 202 in accordance with one or more example embodiments of the invention. FIGS. 2 and 4 will be described in conjunction with one another hereinafter.

An exemplary architecture of a data decompressor 202 in accordance with example embodiments is depicted in FIG. 2. The data decompressor 202 may include a local memory 204 for storing various types of data including, without limitation, quantized prediction errors, quantized data values, and the like. The data decompressor 202 may further include a parameter adjustment engine 208 configured to re-learn and adjust predictive model parameters 210 at each decompression iteration. The data compressor 202 may additionally include a prediction engine 212 that may be configured to perform one-step ahead prediction.

Referring now to FIG. 4 in conjunction with FIG. 2, at block 402 of the method 400, the prediction engine 212 may receive input including N previous quantized data values 214. In example embodiments, the N previous quantized data values may be represented as follows: {ŷ_{t-N}, . . . , ŷₜ₋₁}, where t is current sampling time, and N is model order. In addition, at block 404 of the method 400, the prediction engine 212 may receive learned parameters 210 from a prior decompression iteration. Further, at block 406 of the method 400, the data decompressor may receive from, for example, the data compressor 102 executing on an edge device, a quantized prediction error \hat{ε}ₜ 218.

Then, at block 408 of the method 400, the prediction engine 212 may determine a predicted current data value \tilde{y}ₜ 216 based at least in part on the N previous quantized data values {ŷ_{t-N}, . . . , ŷₜ₋₁} 214 and the learned parameters 210 θₜ₋₁. In example embodiments, the prediction engine 212 of the data decompressor 202 may be identical to the prediction engine 112 of the data compressor 102 in order to ensure that the decompressor 202 calculates the same predicted value \tilde{y}ₜ 216 as the predicted value \tilde{y}ₜ 116 calculated by the prediction engine 112 of the data compressor 102. Thus, in example embodiments, both the prediction engine 112 and the prediction engine 212 may make predictions based on quantized data values rather than actual data values because the data decompressor 202 does not have access to the actual data values but can reconstruct (as described in more detail hereinafter) the quantized data values from predicted values generated by the prediction engine 212 (which are the same predicted values generated by the prediction engine 112) and the quantized prediction errors received from the data compressor 102.

While not depicted in FIG. 2, the prediction engine 212 may include a linear self-learning model and/or a non-linear self-learning model because, as previously described, the prediction engine 212 may be the same as the prediction engine 112. That is, in example embodiments, the linear self-learning model of the prediction engine 212 may be the same NLMS model as the linear model 112A of the prediction engine 112 and the non-linear self-learning model of the prediction engine 212 may be the same LSTM-based neural network as the non-linear model 112B of the prediction engine 112. Further, in example embodiments, just as may be the case with the prediction engine 112, real-time supervised learning algorithms may be implemented to learn the time-variant model parameters 210 utilized by the prediction engine 212. As with the parameters 110, in certain example embodiments, the parameters 210 may be re-learned at each decompression iteration based on historical quantized data values 206. More specifically, in example embodiments, the parameter adjustment engine 208 may learn/re-learn the parameters 210 at each iteration based on the historical quantized data values 206 reconstructed prior to the current sampling time t.

Referring again to FIG. 4, at block 410 of the method 400, a quantized current data value ŷₜ 220 may be reconstructed based at least in part on the quantized prediction error \hat{ε}ₜ 218 (which is the same as the quantized prediction error εₜ 124) and the predicted current data value \tilde{y}ₜ 216. More specifically, at block 410 of the method 400, the quantized current data value ŷₜ 220 may be calculated as the sum of the predicted current data value \tilde{y}ₜ 216 and the quantized prediction error \hat{ε}ₜ 218. In example embodiments, the quantized current data value ŷₜ 220 is ensured to be the same value as the quantized current data value ŷₜ 126 because the quantized prediction error \hat{ε}ₜ 218 is the quantized prediction error εₜ 124 generated at and received from the data compressor 102 and the prediction engine 212 is identical to the prediction engine 112, thereby ensuring that the predicted current data value \tilde{y}ₜ 216 generated by the prediction engine 212 is exactly the same as the predicted current data value \tilde{y}ₜ 116 generated by the prediction engine 112.

At block 412 of the method 400, the quantized current data value ŷₜ 220 may be stored, for example, in the local memory 204. Finally, at block 414 of the method 400, the parameters 210 may be re-learned based at least in part on the quantized current data value ŷₜ 220 that was reconstructed at sampling time t and the N previous quantized data values {ŷ_{t-N}, . . . , ŷₜ₋₁} 214. More specifically, θₜ may be determined based at least in part on (ŷ_{t-N}, . . . , ŷₜ) and θₜ₋₁, and θₜ may be used as the learned parameters 210 during a subsequent decompression iteration at sampling time t+1.

Illustrative pseudocode corresponding to the operation of the data decompressor 202 is shown below.

Input: {ŷ_{t-N}, . . . , ŷₜ₋₁}, {\hat{ε}ₜ}

Output: ŷₜ

For t=1, . . . , T
1. Receive \hat{ε}ₜ from the compressor on edge device;
2. \tilde{y}ₜ=Predictor(ŷ_{t-N}, . . . , ŷₜ₋₁);
3. ŷₜ=\tilde{y}ₜ+\hat{ε}ₜ;
4. θₜ=Learner(ŷ_{t-N}, . . . , ŷₜ, θₜ₋₁).

End

One or more illustrative embodiments of the invention are described herein. Such embodiments are merely illustrative of the scope of this invention and are not intended to be limiting in any way. Accordingly, variations, modifications, and equivalents of embodiments disclosed herein are also within the scope of this invention.

FIG. 5 is a schematic diagram of an illustrative networked architecture 500 configured to implement one or more example embodiments of the invention. The illustrative networked architecture 500 includes one or more cloud devices 502 configured to communicate via one or more networks 506 with one or more network edge devices 504. The cloud device(s) 502 may include, without limitation, one or more servers executing in a cloud environment. The edge device(s) 504 may include, without limitation, a sensor; a processing device that incorporates one or more sensors; a personal computer (PC); a tablet; a smartphone; a wearable device; a voice-enabled device; or the like. Generally speaking, in example embodiments, an edge device 504 may include any device capable of collecting time-series data measurements including, without limitation, speed data; vibration data; power data; temperature data; and so forth. While any particular component of the networked architecture 500 may be described herein in the singular, it should be appreciated that multiple instances of any such component may be provided, and functionality described in connection with a particular component may be distributed across multiple ones of such a component.

The network(s) 506 may include, but are not limited to, any one or more different types of communications networks such as, for example, cable networks, public networks (e.g., the Internet), private networks (e.g., frame-relay networks), wireless networks, cellular networks, telephone networks (e.g., a public switched telephone network), or any other suitable private or public packet-switched or circuit-switched networks. The network(s) 506 may have any suitable communication range associated therewith and may include, for example, global networks (e.g., the Internet), metropolitan area networks (MANs), wide area networks (WANs), local area networks (LANs), or personal area networks (PANs). In addition, the network(s) 506 may include communication links and associated networking devices (e.g., link-layer switches, routers, etc.) for transmitting network traffic over any suitable type of medium including, but not limited to, coaxial cable, twisted-pair wire (e.g., twisted-pair copper wire), optical fiber, a hybrid fiber-coaxial (HFC) medium, a microwave medium, a radio frequency communication medium, a satellite communication medium, or any combination thereof.

In an illustrative configuration, a cloud device 502 may include one or more processors (processor(s)) 508, one or more memory devices 510 (generically referred to herein as memory 510), one or more input/output (“I/O”) interface(s) 512, one or more network interfaces 514, and data storage 518. The cloud device 502 may further include one or more buses 516 that functionally couple various components of the cloud device 502.

The bus(es) 516 may include at least one of a system bus, a memory bus, an address bus, or a message bus, and may permit the exchange of information (e.g., data (including computer-executable code), signaling, etc.) between various components of the cloud device 502. The bus(es) 516 may include, without limitation, a memory bus or a memory controller, a peripheral bus, an accelerated graphics port, and so forth. The bus(es) 516 may be associated with any suitable bus architecture including, without limitation, an Industry Standard Architecture (ISA), a Micro Channel Architecture (MCA), an Enhanced ISA (EISA), a Video Electronics Standards Association (VESA) architecture, an Accelerated Graphics Port (AGP) architecture, a Peripheral Component Interconnects (PCI) architecture, a PCI-Express architecture, a Personal Computer Memory Card International Association (PCMCIA) architecture, a Universal Serial Bus (USB) architecture, and so forth.

The memory 510 may include volatile memory (memory that maintains its state when supplied with power) such as random access memory (RAM) and/or non-volatile memory (memory that maintains its state even when not supplied with power) such as read-only memory (ROM), flash memory, ferroelectric RAM (FRAM), and so forth. Persistent data storage, as that term is used herein, may include non-volatile memory. In certain example embodiments, volatile memory may enable faster read/write access than non-volatile memory. However, in certain other example embodiments, certain types of non-volatile memory (e.g., FRAM) may enable faster read/write access than certain types of volatile memory.

In various implementations, the memory 510 may include multiple different types of memory such as various types of static random access memory (SRAM), various types of dynamic random access memory (DRAM), various types of unalterable ROM, and/or writeable variants of ROM such as electrically erasable programmable read-only memory (EEPROM), flash memory, and so forth. The memory 510 may include main memory as well as various forms of cache memory such as instruction cache(s), data cache(s), translation lookaside buffer(s) (TLBs), and so forth. Further, cache memory such as a data cache may be a multi-level cache organized as a hierarchy of one or more cache levels (L1, L2, etc.).

The data storage 518 may include removable storage and/or non-removable storage including, but not limited to, magnetic storage, optical disk storage, and/or tape storage. The data storage 518 may provide non-volatile storage of computer-executable instructions and other data. The memory 510 and the data storage 518, removable and/or non-removable, are examples of computer-readable storage media (CRSM) as that term is used herein.

The data storage 518 may store computer-executable code, instructions, or the like that may be loadable into the memory 510 and executable by the processor(s) 508 to cause the processor(s) 508 to perform or initiate various operations. The data storage 518 may additionally store data that may be copied to memory 510 for use by the processor(s) 508 during the execution of the computer-executable instructions. Moreover, output data generated as a result of execution of the computer-executable instructions by the processor(s) 508 may be stored initially in memory 510 and may ultimately be copied to data storage 518 for non-volatile storage.

More specifically, the data storage 518 may store one or more operating systems (O/S) 520; one or more database management systems (DBMS) 522 configured to access the memory 510 and/or one or more external datastores 534; and one or more program modules, applications, engines, managers, computer-executable code, scripts, computer-accessible/computer-executable data; or the like such as, for example, a parameter adjustment engine 524; a prediction engine 526; and a quantizer engine 532. Further, in example embodiments, the prediction engine 526 may include a linear learning model 528 and/or a non-linear learning model 530. Any of the components depicted as being stored in data storage 518 may include any combination of software, firmware, and/or hardware. The software and/or firmware may include computer-executable instructions (e.g., computer-executable program code) that may be loaded into the memory 510 for execution by one or more of the processor(s) 508 to perform any of the operations described earlier in connection with correspondingly named modules/engines depicted in FIG. 1.

The data storage 518 may further various types of data (e.g., prior quantized data values; predicted current data values; actual current data values; quantized prediction errors; etc.) utilized by components of the cloud device 502. Any data stored in the data storage 518 may be loaded into the memory 510 for use by the processor(s) 508 in executing computer-executable instructions. In addition, any data stored in the data storage 518 may potentially be stored in the external datastore(s) 534 and may be accessed via the DBMS 522 and loaded in the memory 510 for use by the processor(s) 508 in executing computer-executable instructions.

The processor(s) 508 may be configured to access the memory 510 and execute computer-executable instructions loaded therein. For example, the processor(s) 508 may be configured to execute computer-executable instructions of the various program modules, applications, engines, managers, or the like of the cloud device 502 to cause or facilitate various operations to be performed in accordance with one or more embodiments of the invention. The processor(s) 508 may include any suitable processing unit capable of accepting data as input, processing the input data in accordance with stored computer-executable instructions, and generating output data. The processor(s) 508 may include any type of suitable processing unit including, but not limited to, a central processing unit, a microprocessor, a Reduced Instruction Set Computer (RISC) microprocessor, a Complex Instruction Set Computer (CISC) microprocessor, a microcontroller, an Application Specific Integrated Circuit (ASIC), a Field-Programmable Gate Array (FPGA), a System-on-a-Chip (SoC), a digital signal processor (DSP), and so forth. Further, the processor(s) 508 may have any suitable microarchitecture design that includes any number of constituent components such as, for example, registers, multiplexers, arithmetic logic units, cache controllers for controlling read/write operations to cache memory, branch predictors, or the like. The microarchitecture design of the processor(s) 508 may be capable of supporting any of a variety of instruction sets.

Referring now to other illustrative components depicted as being stored in the data storage 518, the O/S 520 may be loaded from the data storage 518 into the memory 510 and may provide an interface between other application software executing on the cloud device 502 and hardware resources of the cloud device 502. More specifically, the O/S 520 may include a set of computer-executable instructions for managing hardware resources of the cloud device 502 and for providing common services to other application programs. In certain example embodiments, the O/S 520 may include or otherwise control the execution of one or more of the program modules, engines, managers, or the like depicted as being stored in the data storage 518. The O/S 520 may include any operating system now known or which may be developed in the future including, but not limited to, any server operating system, any mainframe operating system, or any other proprietary or non-proprietary operating system.

The DBMS 522 may be loaded into the memory 510 and may support functionality for accessing, retrieving, storing, and/or manipulating data stored in the memory 510, data stored in the data storage 518, and/or data stored in external datastore(s) 534. The DBMS 522 may use any of a variety of database models (e.g., relational model, object model, etc.) and may support any of a variety of query languages. The DBMS 522 may access data represented in one or more data schemas and stored in any suitable data repository. Data stored in the datastore(s) 534 may include, for example, prior quantized data values; predicted current data values; actual current data values; quantized prediction errors; and so forth, any portion of which may alternatively or additionally be stored in the data storage 518. Datastore(s) 534 that may be accessible by the cloud device 502 via the DBMS 522 may include, but are not limited to, databases (e.g., relational, object-oriented, etc.); file systems; flat files; distributed datastores in which data is stored on more than one node of a computer network; peer-to-peer network datastores; or the like.

Referring now to other illustrative components of the cloud device 502, the input/output (I/O) interface(s) 512 may facilitate the receipt of input information by the cloud device 502 from one or more I/O devices as well as the output of information from the cloud device 502 to the one or more I/O devices. The I/O devices may include any of a variety of components such as a display or display screen having a touch surface or touchscreen; an audio output device for producing sound, such as a speaker; an audio capture device, such as a microphone; an image and/or video capture device, such as a camera; a haptic unit; and so forth. Any of these components may be integrated into the cloud device 502 or may be separate. The I/O devices may further include, for example, any number of peripheral devices such as data storage devices, printing devices, and so forth.

The I/O interface(s) 512 may also include an interface for an external peripheral device connection such as universal serial bus (USB), FireWire, Thunderbolt, Ethernet port or other connection protocol that may connect to one or more networks. The I/O interface(s) 512 may also include a connection to one or more antennas to connect to one or more networks via a wireless local area network (WLAN) (such as Wi-Fi) radio, Bluetooth, and/or a wireless network radio, such as a radio capable of communication with a wireless communication network such as a Long Term Evolution (LTE) network, WiMAX network, 3G network, etc.

The cloud device 502 may further include one or more network interfaces 514 via which the cloud device 502 may communicate with any of a variety of other systems, platforms, networks, devices, and so forth. The network interface(s) 514 may enable communication, for example, with an edge device 504 via one or more of the network(s) 506.

In an illustrative configuration, an edge device 504 may include one or more processors (processor(s)) 536, one or more memory devices 538 (generically referred to herein as memory 538), one or more input/output (“I/O”) interface(s) 540, one or more network interfaces 542, and data storage 546. The edge device 504 may further include one or more buses 544 that functionally couple various components of the edge device 504.

The bus(es) 544 may include any of the types of buses and bus architecture previously described in reference to the bus(es) 516 of the cloud device 502. In addition, the memory 538 may include any of the type of memory and memory configuration previously described in reference to the memory 510. Further, the data storage 546 may include any of the types of data storage previously described in reference to the data storage 518. The data storage 546 may provide non-volatile storage of computer-executable instructions and other data. The memory 538 and the data storage 546, removable and/or non-removable, are examples of computer-readable storage media (CRSM) as that term is used herein.

The data storage 546 may store computer-executable code, instructions, or the like that may be loadable into the memory 538 and executable by the processor(s) 536 to cause the processor(s) 536 to perform or initiate various operations. The data storage 546 may additionally store data that may be copied to memory 538 for use by the processor(s) 536 during the execution of the computer-executable instructions. Moreover, output data generated as a result of execution of the computer-executable instructions by the processor(s) 536 may be stored initially in memory 538 and may ultimately be copied to data storage 546 for non-volatile storage.

More specifically, the data storage 546 may store one or more operating systems (O/S) 548; one or more database management systems (DBMS) 548 configured to access the memory 538 and/or the datastore(s) 534; and one or more program modules, applications, engines, managers, computer-executable code, scripts, computer-accessible/computer-executable data; or the like such as, for example, a parameter adjustment engine 552 and a prediction engine 554. Further, in example embodiments, while not depicted in FIG. 5, the prediction engine 554 may include a linear learning model and/or a non-linear learning model. Any of the components depicted as being stored in data storage 546 may include any combination of software, firmware, and/or hardware. The software and/or firmware may include computer-executable instructions (e.g., computer-executable program code) that may be loaded into the memory 538 for execution by one or more of the processor(s) 536 to perform any of the operations described earlier in connection with correspondingly named modules/engines depicted in FIG. 2.

The data storage 546 may further various types of data (e.g., prior quantized data values; predicted current data values; actual current data values; quantized prediction errors; etc.) utilized by components of the edge device 504. Any data stored in the data storage 546 may be loaded into the memory 538 for use by the processor(s) 536 in executing computer-executable instructions. In addition, any data stored in the data storage 546 may potentially be stored in the external datastore(s) 534 and may be accessed via the DBMS 546 and loaded in the memory 538 for use by the processor(s) 536 in executing computer-executable instructions.

The processor(s) 536 may be configured to access the memory 538 and execute computer-executable instructions loaded therein. For example, the processor(s) 536 may be configured to execute computer-executable instructions of the various program modules, applications, engines, managers, or the like of the edge device 504 to cause or facilitate various operations to be performed in accordance with one or more embodiments of the invention. The processor(s) 536 may include any of the type of processing units and microarchitecture designs previously described in reference to the processor(s) 508 of the cloud device 502.

Referring now to other illustrative components depicted as being stored in the data storage 546, the O/S 548 may be loaded from the data storage 546 into the memory 538 and may provide an interface between other application software executing on the edge device 504 and hardware resources of the edge device 504. More specifically, the O/S 548 may include a set of computer-executable instructions for managing hardware resources of the cloud device 502 and for providing common services to other application programs. In certain example embodiments, the O/S 548 may include or otherwise control the execution of one or more of the program modules, engines, managers, or the like depicted as being stored in the data storage 546. The O/S 548 may include any operating system now known or which may be developed in the future including, but not limited to, any server operating system, any mainframe operating system, or any other proprietary or non-proprietary operating system.

The DBMS 550 may be loaded into the memory 538 and may support functionality for accessing, retrieving, storing, and/or manipulating data stored in the memory 538, data stored in the data storage 546, and/or data stored in external datastore(s) 534. The DBMS 550 may use any of a variety of database models (e.g., relational model, object model, etc.) and may support any of a variety of query languages. The DBMS 550 may access data represented in one or more data schemas and stored in any suitable data repository. Any of the types of data previously described as being stored in the datastore(s) 534 may alternatively or additionally be stored in the data storage 546.

Referring now to other illustrative components of the edge device 504, the input/output (I/O) interface(s) 540 may facilitate the receipt of input information by the edge device 504 from one or more I/O devices as well as the output of information from the edge device 504 to the one or more I/O devices. The I/O interface(s) 540 and associated I/O devices may include any of the types of I/O interface(s) and I/O devices previously described in reference to the I/O interface(s) 512 of the cloud device 502.

The edge device 504 may further include one or more network interfaces 542 via which the edge device 504 may communicate with any of a variety of other systems, platforms, networks, devices, and so forth. The network interface(s) 542 may enable communication, for example, with a cloud device 502 via one or more of the network(s) 506.

It should be appreciated that the program modules/engines depicted in FIG. 5 as being stored in the data storage 518 and/or the data storage 546 are merely illustrative and not exhaustive and that processing described as being supported by any particular module may alternatively be distributed across multiple modules, engines, or the like, or performed by a different module, engine, or the like. In addition, various program module(s), script(s), plug-in(s), Application Programming Interface(s) (API(s)), or any other suitable computer-executable code hosted locally on the cloud device 502 and/or other computing devices (e.g., one or more edge devices 504) accessible via the network(s) 506, may be provided to support functionality provided by the engines/modules depicted in FIG. 5 and/or additional or alternate functionality. Further, functionality may be modularized in any suitable manner such that processing described as being performed by a particular engine/module may be performed by a collection of any number of engines/program modules, or functionality described as being supported by any particular engine/module may be supported, at least in part, by another engine/module. In addition, engines/program modules that support the functionality described herein may be executable across any number of cluster members in accordance with any suitable computing model such as, for example, a client-server model, a peer-to-peer model, and so forth. In addition, any of the functionality described as being supported by any of the engines/modules depicted in FIG. 5 may be implemented, at least partially, in hardware and/or firmware across any number of devices.

It should further be appreciated that the cloud device 502 and/or the edge device 504 may include alternate and/or additional hardware, software, or firmware components beyond those described or depicted without departing from the scope of the invention. More particularly, it should be appreciated that software, firmware, or hardware components depicted as forming part of the cloud device 502 and/or the edge device 504 are merely illustrative and that some components may not be present or additional components may be provided in various embodiments. While various illustrative engines/program modules have been depicted and described as software modules stored in data storage 518 and/or the data storage 546, it should be appreciated that functionality described as being supported by the modules may be enabled by any combination of hardware, software, and/or firmware. It should further be appreciated that each of the above-mentioned engines/modules may, in various embodiments, represent a logical partitioning of supported functionality. This logical partitioning is depicted for ease of explanation of the functionality and may not be representative of the structure of software, hardware, and/or firmware for implementing the functionality. Accordingly, it should be appreciated that functionality described as being provided by a particular engine/module may, in various embodiments, be provided at least in part by one or more other engines/modules. Further, one or more depicted engines/modules may not be present in certain embodiments, while in other embodiments, additional engines/program modules not depicted may be present and may support at least a portion of the described functionality and/or additional functionality.

One or more operations the method 300 may be performed by one or more cloud devices 502 having the illustrative configuration depicted in FIG. 5, or more specifically, by one or more program modules, engines, applications, or the like executable on such a device. Similarly, one or more operations the method 400 may be performed by one or more edge devices 504 having the illustrative configuration depicted in FIG. 5, or more specifically, by one or more program modules, engines, applications, or the like executable on such a device. It should be appreciated, however, that such operations may be implemented in connection with numerous other device configurations.

The operations described and depicted in the illustrative methods of FIGS. 3 and 4 may be carried out or performed in any suitable order as desired in various example embodiments of the invention. Additionally, in certain example embodiments, at least a portion of the operations may be carried out in parallel. Furthermore, in certain example embodiments, less, more, or different operations than those depicted in FIGS. 3 and 4 may be performed.

Although specific embodiments of the invention have been described, one of ordinary skill in the art will recognize that numerous other modifications and alternative embodiments are within the scope of the invention. For example, any of the functionality and/or processing capabilities described with respect to a particular system, system component, device, or device component may be performed by any other system, device, or component. Further, while various illustrative implementations and architectures have been described in accordance with embodiments of the invention, one of ordinary skill in the art will appreciate that numerous other modifications to the illustrative implementations and architectures described herein are also within the scope of this invention. In addition, it should be appreciated that any operation, element, component, data, or the like described herein as being based on another operation, element, component, data, or the like may be additionally based on one or more other operations, elements, components, data, or the like. Accordingly, the phrase “based on,” or variants thereof, should be interpreted as “based at least in part on.”

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

What is claimed is:

1. A computer-implemented method for compressing time-series data, the method comprising:
receiving input comprising a plurality of prior quantized data values;
receiving learned parameters of one or more prediction models;
determining, using the one or more prediction models, a predicted current data value based at least in part on the plurality of prior quantized data values and the learned parameters;
determining a prediction error based at least in part on the predicted current data value and an actual current data value;
quantizing the prediction error to obtain a quantized prediction error;
determining a quantized current data value based at least in part on the quantized prediction error and the predicted current data value; and
re-learning the parameters based at least in part on the plurality of prior quantized data values and the quantized current data value.

2. The computer-implemented method of claim 1, further comprising:
compressing the quantized prediction error; and
sending the compressed quantized prediction error to a data decompressor that is configured to reconstruct the quantized current data value based at least in part on the compressed quantized prediction error.

3. The computer-implemented method of claim 1, wherein determining the prediction error based at least in part on the predicted current data value and the actual current data value comprises calculating, as the prediction error, a difference between the predicted current data value and the actual current data value.

4. The computer-implemented method of claim 1, wherein determining the quantized current data value based at least in part on the quantized prediction error and the predicted current data value comprises summing the quantized prediction error and the predicted current data value to obtain the quantized current data value.

5. The computer-implemented method of claim 1, wherein determining the predicted current data value based at least in part on the plurality of prior quantized data values and the learned parameters comprises applying, using the learned parameters, at least one of a linear prediction model or a non-linear prediction model to the plurality of prior quantized data values to obtain the predicted current data value.

6. The computer-implemented method of claim 1, wherein re-learning the parameters based at least in part on the plurality of prior quantized data values and the quantized current data value comprises minimizing a norm of a plurality of quantized prediction errors.

7. A system for compressing time-series data, the system comprising:
at least one processor; and
at least one memory storing computer-executable instructions, wherein the at least one processor is configured to access the at least one memory and execute the computer-executable instructions to:
receive input comprising a plurality of prior quantized data values;
receive learned parameters of one or more prediction models;
determine, using the one or more prediction models, a predicted current data value based at least in part on the plurality of prior quantized data values and the learned parameters;
determine a prediction error based at least in part on the predicted current data value and an actual current data value;
quantize the prediction error to obtain a quantized prediction error;
determine a quantized current data value based at least in part on the quantized prediction error and the predicted current data value; and
re-learn the parameters based at least in part on the plurality of prior quantized data values and the quantized current data value.

8. The system of claim 7, wherein the at least one processor is further configured to execute the computer-executable instructions to:
compress the quantized prediction error; and
send the compressed quantized prediction error to a data decompressor that is configured to reconstruct the quantized current data value based at least in part on the compressed quantized prediction error.

9. The system of claim 7, wherein the at least one processor is configured to determine the prediction error based at least in part on the predicted current data value and the actual current data value by executing the computer-executable instructions to calculate, as the prediction error, a difference between the predicted current data value and the actual current data value.

10. The system of claim 7, wherein the at least one processor is configured to determine the quantized current data value based at least in part on the quantized prediction error and the predicted current data value by executing the computer-executable instructions to sum the quantized prediction error and the predicted current data value to obtain the quantized current data value.

11. The system of claim 7, wherein the at least one processor is configured to determine the predicted current data value based at least in part on the plurality of prior quantized data values and the learned parameters by executing the computer-executable instructions to apply, using the learned parameters, at least one of a linear prediction model or a non-linear prediction model to the plurality of prior quantized data values to obtain the predicted current data value.

12. The system of claim 7, wherein the at least one processor is configured to re-learn the parameters based at least in part on the plurality of prior quantized data values and the quantized current data value by executing the computer-executable instructions to minimize a norm of a plurality of quantized prediction errors.

13. A computer program product for compressing time-series data, the computer program product comprising a storage medium readable by a processing circuit, the storage medium storing instructions executable by the processing circuit to cause a method to be performed, the method comprising:
receiving input comprising a plurality of prior quantized data values;
receiving learned parameters of one or more prediction models;
determining, using the one or more prediction models, a predicted current data value based at least in part on the plurality of prior quantized data values and the learned parameters;
determining a prediction error based at least in part on the predicted current data value and an actual current data value;
quantizing the prediction error to obtain a quantized prediction error;
determining a quantized current data value based at least in part on the quantized prediction error and the predicted current data value; and
re-learning the parameters based at least in part on the plurality of prior quantized data values and the quantized current data value.

14. The computer program product of claim 13, the method further comprising:
compressing the quantized prediction error; and
sending the compressed quantized prediction error to a data decompressor that is configured to reconstruct the quantized current data value based at least in part on the compressed quantized prediction error.

15. The computer program product of claim 13, wherein determining the prediction error based at least in part on the predicted current data value and the actual current data value comprises calculating, as the predicted error, a difference between the predicted current data value and the actual current data value.

16. The computer program product of claim 13, wherein determining the quantized current data value based at least in part on the quantized prediction error and the predicted current data value comprises summing the quantized prediction error and the predicted current data value to obtain the quantized current data value.

17. The computer program product of claim 13, wherein determining the predicted current data value based at least in part on the plurality of prior quantized data values and the learned parameters comprises applying, using the learned parameters, at least one of a linear prediction model or a non-linear prediction model to the plurality of prior quantized data values to obtain the predicted current data value.

18. The computer program product of claim 13, wherein re-learning the parameters based at least in part on the plurality of prior quantized data values and the quantized current data value comprises minimizing a norm of a plurality of quantized prediction errors.

19. A computer-implemented method for decompressing compressed time-series data, the method comprising:
receiving input comprising a plurality of prior quantized data values;
receiving learned parameters of one or more prediction models;
receiving, from a data compressor, a compressed quantized prediction error;
decompressing the compressed quantized prediction error to obtain a quantized prediction error;
determining, using the one or more prediction models, a predicted current data value based at least in part on the plurality of prior quantized data values and the learned parameters;
reconstructing a quantized current data value based at least in part on the quantized prediction error and the predicted current data value; and
re-learning the parameters based at least in part on the plurality of prior quantized data values and the quantized current data value.

20. The computer-implemented method of claim 19, wherein the compressed quantized prediction error is received from a network edge device, and wherein the quantized current data value is reconstructed at a cloud device.
